(19) United States
(12) Patent Application Publication
(10) Pub. No.: US 2026/0170222 A1
(43) Pub. Date: Jun. 18, 2026

(54) Circuit Layout Hotspot Detection System Capable of Predicting Potential Circuit Defects

(71) Applicant: UNITED MICROELECTRONICS CORP., Hsin-Chu City (TW)

(72) Inventors: Pin-Yen Tsai, Hsinchu City (TW); Hao-Chiang Shao, Taoyuan City (TW)

(73) Assignee: UNITED MICROELECTRONICS CORP., Hsin-Chu City (TW)

(21) Appl. No.: 19/006,133

(22) Filed: Dec. 30, 2024

(30) Foreign Application Priority Data
Dec. 13, 2024 (TW) 113148538

(51) Int. Cl. G06F 30/398

(52) U.S. Cl. CPC G06F 30/398

(57) ABSTRACT

A circuit layout hotspot detection system includes a lithography simulator, an object detector, and a cross-model feature fusion module. The lithography simulator is used to receive circuit layout data to generate a layout deformation feature matrix. The object detector is coupled to the lithography simulator for generating a plurality of layout pattern feature matrices based on the circuit layout data. The cross-model feature fusion module is coupled to the lithography simulator and the object detector for generating potential abnormal hotspot data corresponding to the circuit layout data based on the plurality of layout pattern feature matrices and the layout deformation feature matrix. The circuit layout data includes at least one circuit layout layer. The potential abnormal hotspot data includes a location and a size of at least one potential abnormal hotspot.

### BACKGROUND OF THE INVENTION

### 1. Field of the Invention

The present invention illustrates a circuit layout hotspot detection system, and more particularly, a circuit layout hotspot detection system capable of predicting potential circuit defects.

### 2. Description of the Prior Art

As process nodes shrink and transistor density increases, wafer defect inspection has become more challenging. Traditional methods primarily use a scanning electron microscope (SEM) to inspect wafers. However, this approach requires a plurality of high-resolution SEM images, which increases both time and labor costs.

In recent years, machine learning-based hotspot detection methods have emerged, utilizing convolutional neural network (CNN) object detection models to identify problematic layout patterns. However, these methods have limited generalization ability, making it challenging to address potential circuit layout defects not present in the training data. Current hotspot detection techniques focus on identifying problematic layout patterns but do not account for possible deformation of circuit patterns during the lithography process or the interactions between different layers in the circuit layout. Consequently, they cannot accurately predict potential hotspot areas.

### SUMMARY OF THE INVENTION

In an embodiment, a circuit layout hotspot detection system is disclosed. The circuit layout hotspot detection system comprises a lithography simulator, an object detector, and a cross-model feature fusion module. The lithography simulator is used to receive circuit layout data to generate a layout deformation feature matrix. The object detector is coupled to the lithography simulator for generating a plurality of layout pattern feature matrices based on the circuit layout data. The cross-model feature fusion module is coupled to the lithography simulator and the object detector for generating potential abnormal hotspot data corresponding to the circuit layout data based on the plurality of layout pattern feature matrices and the layout deformation feature matrix. The circuit layout data comprises at least one circuit layout layer. The potential abnormal hotspot data comprises the location and size of at least one potential abnormal hotspot.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a circuit layout hotspot detection system according to an embodiment of the present invention.

FIG. 2 is an architectural diagram of a lithography simulator of the circuit layout hotspot detection system in FIG. 1.

FIG. 3 is an architectural diagram of an object detector of the circuit layout hotspot detection system in FIG. 1.

FIG. 4 is an architectural diagram of a cross-model feature fusion module of the circuit layout hotspot detection system in FIG. 1.

FIG. 5 is an architectural diagram of a cross-model feature fusion unit of the circuit layout hotspot detection system in FIG. 1.

FIG. 6 is an architectural diagram of a first self-attention module of the cross-model feature fusion unit of the circuit layout hotspot detection system in FIG. 1.

FIG. 7 is an architectural diagram of a second self-attention module of the cross-model feature fusion unit of the circuit layout hotspot detection system in FIG. 1.

FIG. 8 is an architectural diagram of a cross-attention module of the cross-model feature fusion unit of the circuit layout hotspot detection system in FIG. 1.

FIG. 9 is a schematic diagram of predicted layout patterns and potential abnormal hotspot data of the circuit layout hotspot detection system in FIG. 1.

### DETAILED DESCRIPTION

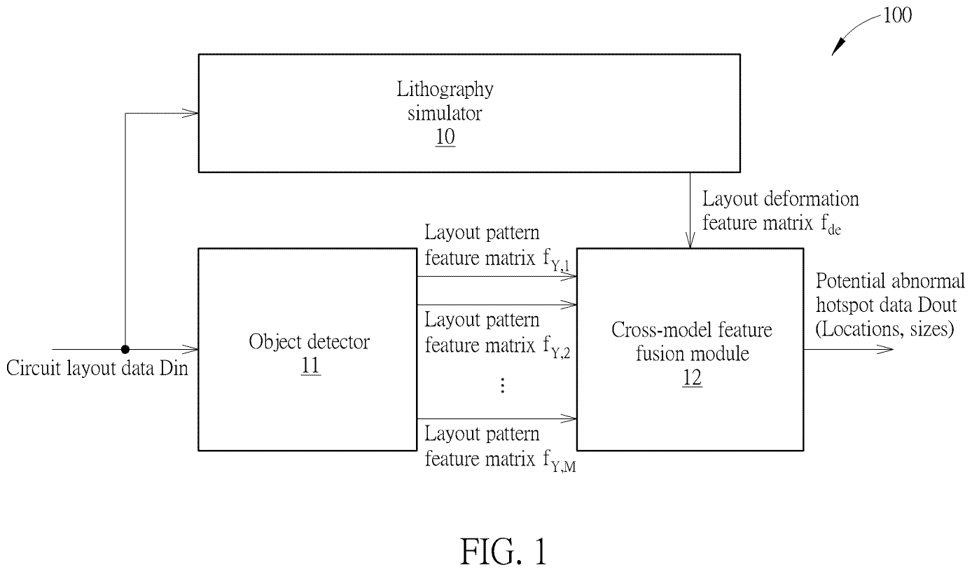

FIG. 1 is a block diagram of a circuit layout hotspot detection system 100 according to an embodiment of the present invention. The circuit layout hotspot detection system 100 can provide high accuracy to identify hotspot regions in circuit layouts affected by shape deformation, and can predict potential hotspot regions. It should be understood that, in integrated circuit design, the hotspot regions affected by shape deformation refer to the regions in the circuit layouts that may lead to defects or performance issues due to shape deformation caused by processes such as lithography and/or etching. During the actual manufacturing process, the circuit layout patterns in these regions may deviate from the expected design due to the limitations of lithography and/or etching technologies, such as narrowed line width, rough line edges, and even broken or short lines, thereby affecting circuit reliability and performance. In FIG. 1, the circuit layout hotspot detection system 100 includes a lithography simulator 10, an object detector 11, and a cross-model feature fusion module 12. The lithography simulator 10 is used for receiving circuit layout data Din to generate a layout deformation feature matrix f_{de}. The circuit layout data Din may include geometry and location details of the integrated circuit design and process machine parameters. The circuit layout data Din is not limited to a single layer but includes a comprehensive representation of the circuit structure, possibly including the current circuit layout layer (e.g., n-th layer) and all preceding circuit layout layers (e.g., up to n−1 layers). Each circuit layout layer in the circuit layout data Din provides a geometric description of the circuit elements and their interconnections. The circuit layout data Din can be acquired from various sources and formats, such as Graphic Data System II (GDSII) files. The object detector 11 is coupled to the lithography simulator 10 and is used for generating a plurality of layout pattern feature matrices f_{Y,1} to f_{Y,M} based on the circuit layout data Din. M is a positive integer. The cross-model feature fusion module 12 is coupled to the lithography simulator 10 and the object detector 11. The cross-model feature fusion module 12 is used for generating potential abnormal hotspot data Dout corresponding to the circuit layout data Din based on the plurality of layout pattern feature matrices f_{Y,1} to f_{Y,M} and the layout deformation feature matrix f_{de}. In this embodiment, the circuit layout data Din includes at least one circuit layout layer. The potential abnormal hotspot data includes a location of the at least one potential abnormal hotspot and a size of the at least one potential abnormal hotspot. It should be understood that the “matrix” in the embodiment can be a multi-dimensional tensor numerical array. For example, a matrix having dimensions HL×WL×KL can be introduced. The structure and operational details of the circuit layout hotspot detection system 100 are illustrated below.

The circuit layout hotspot detection system 100 is based on the mechanism of a neural network to identify and predict potential hotspot (abnormal hotspot) regions. Therefore, the circuit layout hotspot detection system 100 can perform a training stage and an inference stage. For example, in the training stage, the lithography simulator 10 performs a pre-training process. The pre-training process can involve a deep learning-based training stage for predicting the shape changes of the integrated circuit layout after the lithography process. In an embodiment, first, a large number of layout patterns and corresponding binarized scanning electron microscope (SEM) images as well as process machine parameters can be collected as training data. The layout pattern includes the geometric shape and location details of the integrated circuit design. The SEM image is the scanning image of the circuit pattern after actual manufacturing. Then, a convolutional neural network (CNN) can be used for learning the mapping relationship between the layout patterns and the SEM image. The training objective is to minimize the difference between the predicted layout deformation map and the actual binarized SEM image. The layout deformation map is an image with the same dimensions as the input layout patterns, where each pixel value indicates the degree of deformation at the corresponding location, such as a change in line width or an offset of an edge of the input layout patterns. After the lithography simulator 10 is fully trained, it can be used to predict the shape change of new layout patterns after the lithography process. The predicted layout deformation map can facilitate identifying the hotspot regions affected by shape deformation more accurately. In an embodiment, the lithography simulator 10 can be trained by using the circuit layout training data including at least one circuit layout layer and the corresponding binarized electron microscope layout image training data after the lithography or the etching process. Similarly, it aims to minimize a difference between the layout deformation feature matrix and an actual binarized SEM layout image.

In the training stage, the object detector 11 can be trained to identify potential hotspots in circuit layout patterns. In an embodiment, first, the object detector 11 is pre-trained with a set of labeled circuit layout pattern data so that it can identify known hotspot types. The goal of pre-training the object detector 11 is to minimize a difference between the predicted hotspot locations and the actual hotspot locations. In the circuit layout hotspot detection system 100, a backbone of the object detector 11 can use a residual network and a feature pyramid network. The residual network transforms the input layout patterns into multi-level feature tensors (hereinafter, say, feature channels). The feature pyramid network generates feature tensors of different observation scales by using these multi-level feature tensors (feature channels) for the subsequent object identification and classification. In addition, in the training stage, a joint training process can also be performed by the circuit layout hotspot detection system 100. For example, the lithography simulator 10 and object detector 11 can be jointly trained by using the same labeled layout pattern dataset. During joint training, the lithography simulator 10 extracts the shape deformation features of the layout pattern data Din. The object detector 11 extracts the pattern features of the layout pattern data Din. The shape deformation features and the pattern features are then fused through a cross-attention module to improve the accuracy of hotspot detection. During joint training, the parameters of the lithography simulator 10 and the object detector 11 are updated simultaneously to optimize the overall performance of the system. Any reasonable training method and hardware modification falls into the scope of the embodiments. In the following, operational details and architecture of the circuit layout hotspot detection system 100 in the inference stage are illustrated.

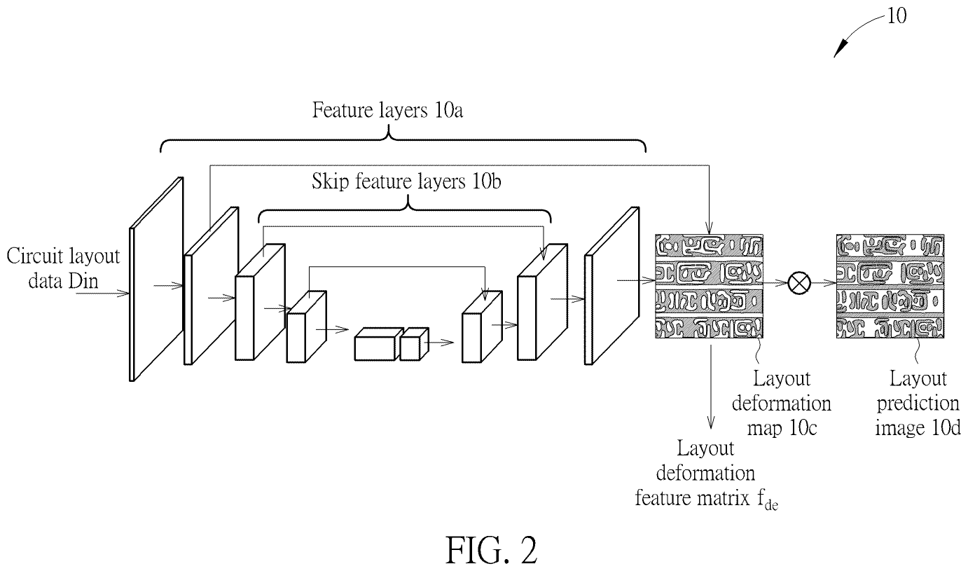

FIG. 2 is an architectural diagram of the lithography simulator 10 of the circuit layout hotspot detection system 100. The lithography simulator 10 includes a plurality of feature layers 10a. The plurality of feature layers 10a are linked to one another and used for receiving circuit layout data Din. Moreover, a portion of the feature layers 10a includes a plurality of skip feature layers 10b. The skip feature layers 10b establish connections between non-adjacent feature layers, and are used for increasing the efficiency of the feature layers in transmitting a gradient signal. More specifically, the lithography simulator 10 simulates the lithography and etching steps in an integrated circuit manufacturing process for predicting the shape changes of circuit layouts. The feature layers 10a extract multi-scale features of the circuit layout data Din. These features include structural and compositional information of the circuit patterns. The skip feature layers 10b can allow data to skip one or more network layers. Thus, data can be directly transmitted to subsequent network layers. This design helps to mitigate the vanishing gradient problem, enabling the model to train deeper networks for improving the training efficiency and accuracy. The lithography simulator 10 may further include a layout deformation map 10c. The layout deformation map 10c is used for providing a visualization of the circuit pattern deformation to assist technicians in better understanding the impact of the lithography process on the circuit layout, such as areas sensitive to the lithography process, changes in line widths, or edge offsets. The lithography simulator 10 may output a layout prediction image 10d and a layout deformation feature matrix f_{de}, based on the layout deformation map 10c. The layout deformation feature matrix f_{de} is extracted from the layout deformation map 10c and can be represented by a numerical matrix or a vector. The layout prediction image 10d is used for displaying an image of the predicted circuit pattern shapes, reflecting the impact of the lithography process on the circuit layout. The layout prediction image 10d may be displayed individually or superimposed on the layout deformation map 10c to provide a clearer representation of the deformation of the circuit patterns.

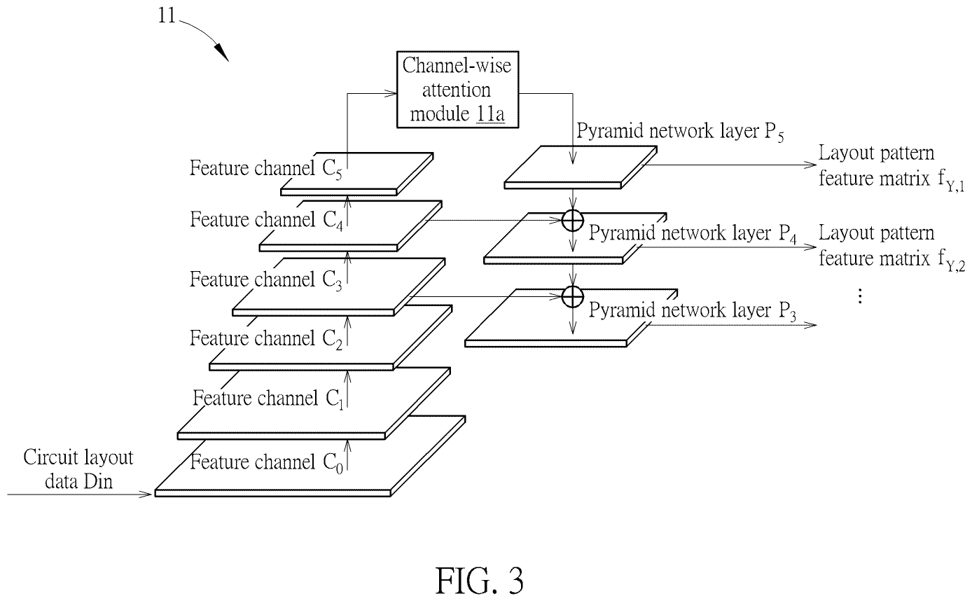

FIG. 3 is an architectural diagram of the object detector 11 of the circuit layout hotspot detection system 100. The object detector 11 may include a plurality of feature channels C₀ to C₅, a plurality of pyramid network layers P₃ to P₅, and a channel-wise attention module 11a. The feature channels C₀ to C₅ are used for receiving and transmitting the circuit layout data Din. The feature channels C₀ to C₅ are linked to one another. The feature channels C₀ to C₅ correspond to layout information at different scales, for example, from low-level features (such as edges and corners) to high-level features (such as structural information). This information can be used to identify potential hotspots in the circuit layout. For example, in a residual network, the feature channels C₀ to C₅ may correspond to outputs of different convolution stages. The shallower feature channels (e.g., C₁, C₂) may capture detailed information on the layout patterns, such as the edges and orientations of lines. The deeper feature channels (e.g., C₄, C₅) may extract more abstract structural information, such as the types and neighboring relations of circuit elements. The feature information at different scales may assist the object detector 11 in analyzing the circuit layout more comprehensively and identifying potential hotspot regions more accurately. The pyramid network layers P₃ to P₅ are used for fusing the feature channels at different levels and generate a multi-scale feature pyramid with rich structural information. The pyramid network layers P₃ to P₅ are linked to one another, forming a top-down pathway and lateral connections, which are used for transmitting high-level structural information to low-level feature channels, thereby improving the detection performance of small objects. In other words, in the pyramid network layers P₃ to P₅, a portion of the pyramid network layers is linked to a portion of the feature channels to fuse feature channels at different levels. For example, the pyramid network layer P₅ performs sampling on the feature channel C₅ through the channel-wise attention module 11a and fuses it with the feature channel C₄. The pyramid network layer P4 performs sampling on the fused output of the pyramid network layer P5, and fuses it with the feature channel C₃. Then, the pyramid network layer P3 performs sampling on fused output of the pyramid network layer P4. In one embodiment, the fused output of the pyramid network layer P4 can be fused with the feature channel C₂. The channel-wise attention module 11a can enhance the features extracted by the object detector 11 from the circuit layout data Din. The channel-wise attention module 11a is linked to the deepest feature channel (e.g., C₅) among the feature channels C₀ to C₅ and the coarsest pyramid network layer (e.g., P₅) among the pyramid network layers (P₃ to P₅) to enhance a shape representation property of a feature tensor transmitted in the object detector 11. In an embodiment, the operational concept of the channel-wise attention module 11a originates from the convolutional block attention module (CBAM). By introducing the channel-wise attention module 11a, the object detector 11 can provide high efficiency to capture the shape information of polygons in the layout patterns and can learn more representative features.

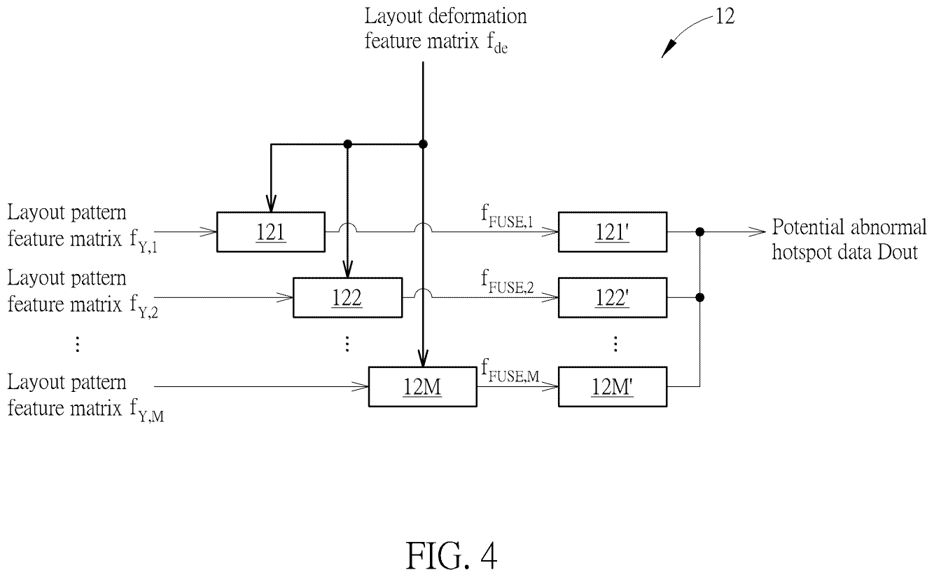

FIG. 4 is an architectural diagram of a cross-model feature fusion module 12 of the circuit layout hotspot detection system 100. The cross-model feature fusion module 12 may include a plurality of cross-model feature fusion units 121 to 12M. Each cross-model feature fusion unit is linked to a corresponding feature pyramid network layer and the lithography simulator 10 for receiving the layout deformation feature matrix f_{de} and a corresponding layout pattern feature matrix f_{Y,1} to f_{Y,M}. For example, the cross-model feature fusion unit 121 receives the layout deformation feature matrix f_{de} and the layout pattern feature matrix f_{Y,1} for outputting a fused feature matrix f_{FUSE,1}. The cross-model feature fusion unit 122 receives the layout deformation feature matrix f_{de} and the layout pattern feature matrix f_{Y,2} for outputting a fused feature matrix f_{FUSE,2}, and so on. The cross-model feature fusion unit 12M receives the layout deformation feature matrix f_{de} and the layout pattern feature matrix f_{Y,M} for outputting a fused feature matrix f_{FUSE,M}. The cross-model feature fusion module 12 may further include a plurality of prediction modules 121′ to 12M′. Each prediction module is linked to a corresponding cross-model feature fusion unit. The prediction modules 121′ to 12M′ are used for outputting the potential abnormal hotspot data Dout.

In one embodiment, each of the plurality of prediction modules 121′ to 12M′ may include a classification subnet and a bounding box regression subnet. The prediction modules 121′ to 12M′ may set a plurality of anchors previously defined. The classification subnet is used for predicting whether each anchor includes at least one potential abnormal hotspot, and predicting a category of the at least one potential abnormal hotspot. The anchors are a plurality of reference frames preset on the layout pattern feature matrix, used for covering different sizes and shapes of potential abnormal hotspots. The bounding box regression subnet is used for predicting the location and the size of the at least one potential abnormal hotspot, that is, predicting an offset between an anchor and an actual hotspot frame. By using the cooperation of the classification subnet and the bounding box regression subnet in each prediction module, the prediction modules 121′ to 12M′ can accurately identify the category, location, and size of the at least one potential abnormal hotspots, and output this information as the potential abnormal hotspot data Dout. The architecture of the cross-model feature fusion unit is illustrated below.

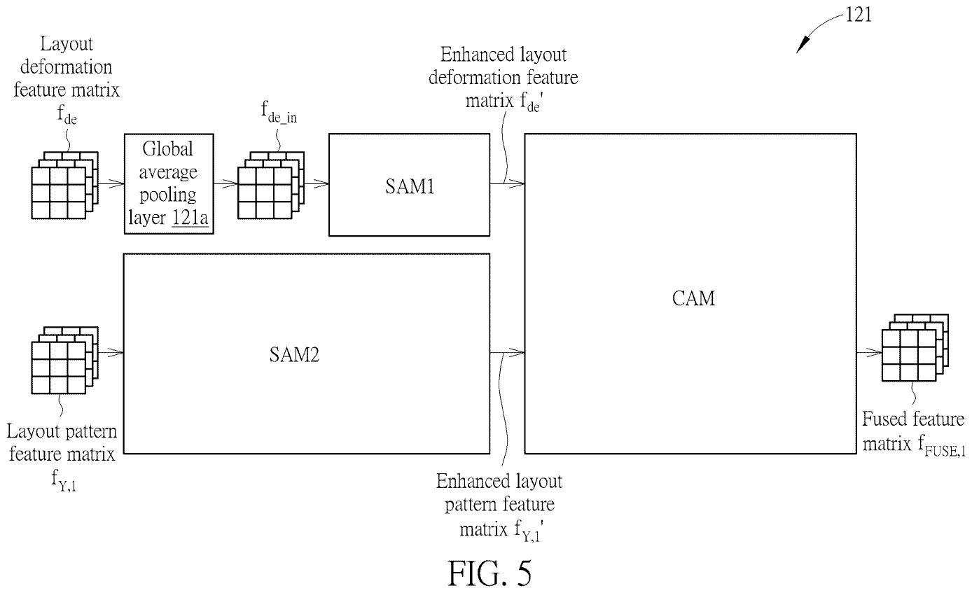

FIG. 5 is an architectural diagram of the cross-model feature fusion unit 121 of the circuit layout hotspot detection system 100. It should be understood that the architectures of the cross-model feature fusion units 121 to 12M are similar. For simplicity, the cross-model feature fusion unit 121 is introduced for illustration hereinafter. The cross-model feature fusion unit 121 includes a first self-attention module SAM1, a second self-attention module SAM2, and a cross-attention module CAM. The first self-attention module SAM1 is linked to the lithography simulator 10 and used for receiving the layout deformation feature matrix f_{de} and outputting an enhanced layout deformation feature matrix f_{de}′. It should be understood that, if there is a need to adjust the dimension of the layout deformation feature matrix f_{de}, a global average pooling layer 121a can be added between the lithography simulator 10 and the first self-attention module SAM1 to reduce the spatial dimension of the layout deformation feature matrix f_{de} to the same dimension as the layout pattern feature matrices f_{Y,1} to f_{Y,M}. The global average pooling layer 121a outputs a layout deformation input matrix f_{de_in} to the first self-attention module SAM1. The second self-attention module SAM2 is linked to the object detector 11 and used for receiving the layout pattern feature matrix f_{Y,1} and outputting an enhanced layout pattern feature matrix f_{Y,1}′. The cross-attention module CAM is linked to the first self-attention module SAM1 and the second self-attention module SAM2 and used for receiving the enhanced layout deformation feature matrix f_{de}′ and the enhanced layout pattern feature matrix f_{Y,1}′ to generate the fused feature matrix f_{FUSE,1}. In other words, the cross-model feature fusion unit 121 utilizes two self-attention modules and one cross-attention module to fuse the information of the layout deformation feature and the layout pattern feature.

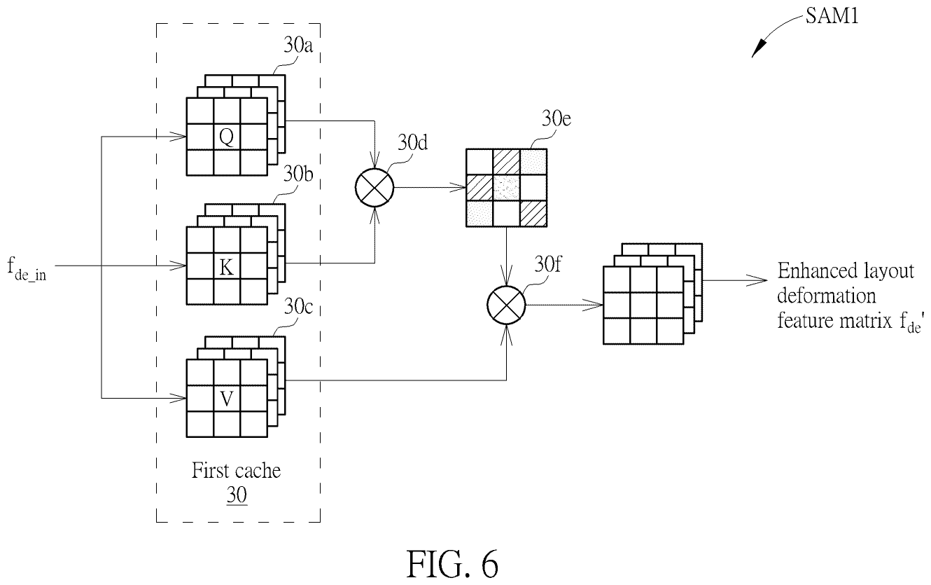

FIG. 6 is an architectural diagram of the first self-attention module SAM1 of the cross-model feature fusion unit 121 of the circuit layout hotspot detection system 100. The first self-attention module SAM1 includes a first cache 30, a first Softmax module 30d, a first attention map module 30e, and a first matrix dot product module 30f. The first self-attention module SAM1 is used for generating a first key tensor matrix 30b, a first value tensor matrix 30c, and a first query tensor matrix 30a, based on the layout deformation feature matrix f_{de} (or the layout deformation input matrix f_{de_in}). The first key tensor matrix 30b, the first value tensor matrix 30c, and the first query tensor matrix 30a are buffered in the first cache 30. For example, after receiving the layout deformation input matrix f_{de_in}, the cross-model feature fusion unit 121 can perform a linear operation to convert the layout deformation input matrix f_{de_in} into the first key tensor matrix 30b, the first value tensor matrix 30c, and the first query tensor matrix 30a. In one embodiment, the first key tensor matrix 30b can be represented as W_{K1}×f_{de_in}. The first value tensor matrix 30c can be represented as W_{V1}×f_{de_in}. The first query tensor matrix 30a can be represented as W_{Q1}×f_{de_in}, where W_{K1}, W_{V1}, and W_{Q1} are different weight matrices. These weight matrices W_{K1}, W_{V1}, and W_{Q1} have learnable parameters that are continuously updated during the model training process.

The first Softmax module 30d is used for converting attention scores to attention weights. These weights are used for calculating the attention map. In one embodiment, after the first query tensor matrix 30a and the first key tensor matrix 30b are generated, the similarity between the first query tensor matrix 30a and the first key tensor matrix 30b can be calculated to acquire a plurality of attention scores. The similarity can be calculated using different methods, such as a dot product or cosine similarity. Then, the first Softmax module 30d can input the attention scores into a Softmax function to convert them into a plurality of attention weights. The Softmax function converts each attention score into a value between 0 and 1. The sum of all attention weights is equal to 1. Conceptually, the attention weights can be regarded as probabilities of a distribution function, used for representing the relative importance of different locations in the layout deformation feature matrix f_{de}. Important locations are given higher weights, while unimportant locations are given lower weights.

The first attention map module 30e is generated based on the output of the first Softmax module 30d. The first attention map module 30e can display an illustration of the degree of attention paid to different parts and can be regarded as a data visualization tool to help engineers understand the operating mechanism of the model. The first attention map module 30e can be presented in the form of a matrix. Each element in the matrix represents the attention weight corresponding to the input data of the model. The higher the weight, the more the model pays attention to the part, and it is considered to have a greater impact on the final result. The first matrix dot product module 30f performs a dot product operation on the output of the attention map module 30e and the first value tensor matrix 30c. As mentioned above, the first value tensor matrix 30c includes the information of the layout deformation input matrix f_{de_in}. The output of the attention map module 30e represents the degree of attention of the model to different parts of the layout deformation input matrix f_{de_in}. By using the dot product operation, the first matrix dot product module 30f can filter out important feature information. In FIG. 6, the output of the first matrix dot product module 30f is called as the enhanced layout deformation feature matrix f_{de}′.

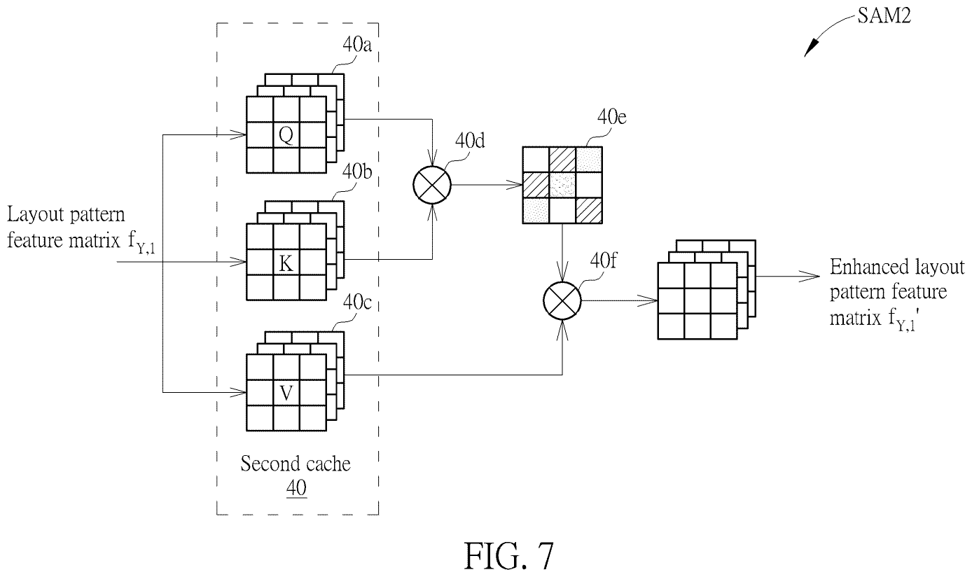

FIG. 7 is an architectural diagram of the second self-attention module SAM2 of the cross-model feature fusion unit 121 of the circuit layout hotspot detection system 100. The second self-attention module SAM2 includes a second cache 40, a second Softmax module 40d, a second attention map module 40e, and a second matrix dot product module 40f. Based on the layout pattern feature matrix f_{Y,1}, the second self-attention module SAM2 can generate a second key tensor matrix 40b, a second value tensor matrix 40c, and a second query tensor matrix 40a. The second key tensor matrix 40b, the second value tensor matrix 40c, and the second query tensor matrix 40a are buffered in the second cache 40. For example, after receiving the layout pattern feature matrix f_{Y,1}, the cross-model feature fusion unit 121 can perform a linear operation to convert the layout pattern feature matrix f_{Y,1} into the second key tensor matrix 40b, the second value tensor matrix 40c, and the second query tensor matrix 40a. In one embodiment, the second key tensor matrix 40b can be expressed as W_{K2}×f_{Y,1}. The second value tensor matrix 40c can be expressed as W_{V2}×f_{Y,1}. The second query tensor matrix 40a can be expressed as W_{Q2}×f_{Y,1}. Here, W_{K2}, W_{V2}, and W_{Q2} are different weight matrices. These weight matrices, W_{K2}, W_{V2}, and W_{Q2}, are learnable parameters that are continuously updated during the model training process. Operations and functions of the second Softmax module 40d, the second attention map module 40e, and the second matrix dot product module 40f in the second self-attention module SAM2 are similar to those of the first self-attention module SAM1 Therefore, details are omitted here. Based on the layout pattern feature matrix f_{Y,1}, the second self-attention module SAM2 outputs an enhanced layout pattern feature matrix f_{Y,1}′.

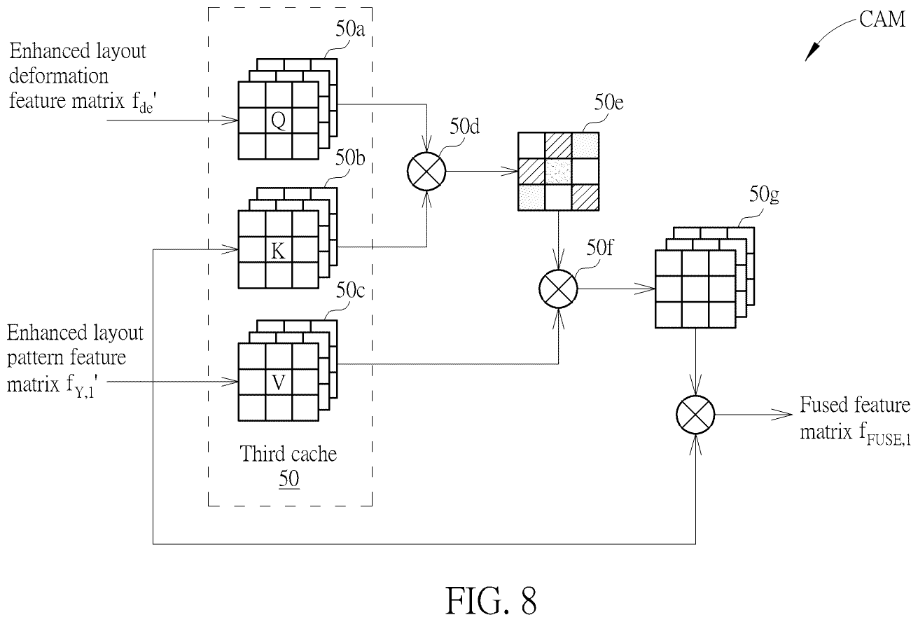

FIG. 8 is an architectural diagram of the cross-attention module CAM of the cross-model feature fusion unit 121 of the circuit layout hotspot detection system 100. The cross-attention module CAM includes a third cache 50, a third Softmax module 50d, a third attention map module 50e, a third matrix dot product module 50f, and a cross-attention feature mask 50g. Based on the output (enhanced layout deformation feature matrix f_{de}′) of the first self-attention module SAM1, the cross-attention module CAM generates a third query tensor matrix 50a. Based on the output (enhanced layout pattern feature matrix f_{Y,1}′) of the second self-attention module SAM2, the cross-attention module CAM generates a third key tensor matrix 50b and a third value tensor matrix 50c. It should be understood that the third query tensor matrix 50a can be acquired by performing linear operations on the enhanced layout deformation feature matrix f_{de}′. Similarly, the third key tensor matrix 50b and the third value tensor matrix 50c can be acquired by performing linear operations on the enhanced layout pattern feature matrix f_{Y,1}′. The operations and functions of the third Softmax module 50d, the third attention map module 50e, and the third matrix dot product module 50f in the cross-attention module CAM are similar to those of the first self-attention module SAM1 and the second self-attention module SAM2. Therefore, details are omitted here. In FIG. 8, the cross-attention feature mask 50g of the cross-attention module CAM can be used to highlight key areas focused on by the model to enhance the performance of the circuit layout hotspot detection system 100. In one embodiment, the cross-attention module CAM receives the enhanced layout deformation feature matrix f_{de}′ and the enhanced layout pattern feature matrix f_{Y,1}′ as inputs and calculates the similarity or correlation between them. The cross-attention feature mask 50g can be adjusted with weights based on the third attention map 50e and the third query tensor matrix 50a to enhance or suppress the influence of specific areas. The output of the cross-attention feature mask 50g is added to the enhanced layout pattern feature matrix f_{Y,1}′ to generate the fused feature matrix f_{FUSE,1}.

In short, in the circuit layout hotspot detection system 100, each cross-model feature fusion unit includes two self-attention modules and one cross-attention module. One self-attention module is used for enhancing the shape-deformation feature generated by the lithography simulator 10. Another self-attention module is used for processing the pattern feature from the feature pyramid network. Then, the two enhanced feature tensors are input into the cross-attention module for cross-model feature fusion.

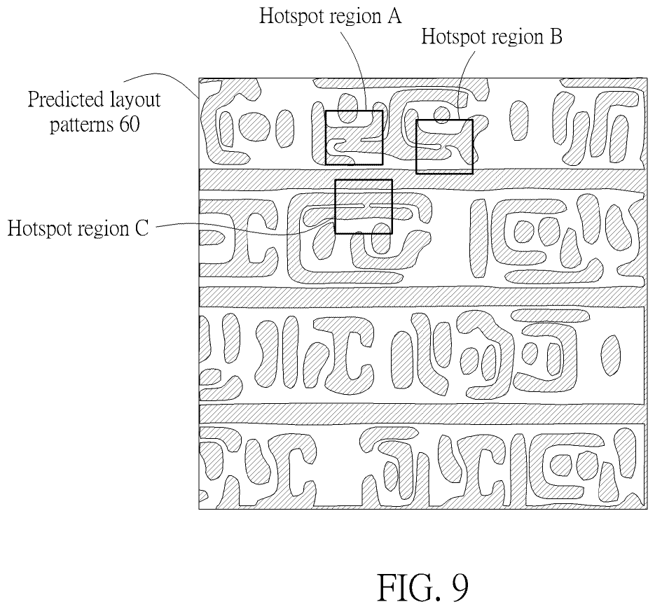

FIG. 9 is a schematic diagram of predicted layout patterns 60 and potential abnormal hotspot data Dout of the circuit layout hotspot detection system 100. As mentioned above, the potential abnormal hotspot data Dout may include a location of at least one potential abnormal hotspot and a size of the at least one potential abnormal hotspot. The predicted layout patterns 60 can be displayed in the form of an image. For example, three hotspot regions A, B, and C are displayed on the layout prediction patterns 60. The hotspot regions A, B, and C correspond to the regions where defects or performance issues may occur in the actual manufacturing process. The hotspot regions A, B, and C can be identified and predicted through the circuit layout hotspot detection system 100. For example, the prediction module (121′ to 12M′) in the circuit layout hotspot detection system 100 includes the classification subnet and the bounding box regression subnet. The classification subnet can predict which regions in the layout prediction pattern 60 include hotspots and predict the categories of the hotspots. The bounding box regression subnet can predict the precise locations and sizes of the hotspots. For example, a bounding box is used for framing the hotspot region. In FIG. 9, the hotspot regions A, B, and C are marked with bounding boxes and regarded as potential abnormal hotspot regions. It should be understood that the potential abnormal hotspot data Dout may include the abnormal hotspot data of the n-th circuit layout layer (current layer). The potential abnormal hotspot data Dout can be used for subsequent analysis and processing. For example, performing more detailed inspections on these hotspot regions A, B, and C or modifying the layout patterns to avoid processing defects.

In summary, the embodiments illustrate a circuit layout hotspot detection system. The circuit layout hotspot detection system integrates a pre-trained lithography simulator and an object detector, and uses a cross-model feature fusion module to combine the features of the two for identifying hotspot regions in the integrated circuit layout where defects may occur, particularly the hotspot regions affected by shape deformation. The circuit layout hotspot detection system can not only improve the accuracy and generalization ability of hotspot detection but can also be used for predicting new hotspots that do not appear in the training data. Therefore, the circuit layout hotspot detection system can improve the yield and reliability of integrated circuits and reduce production costs.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A circuit layout hotspot detection system comprising:
a lithography simulator configured to receive circuit layout data to generate a layout deformation feature matrix;
an object detector coupled to the lithography simulator and configured to generate a plurality of layout pattern feature matrices based on the circuit layout data; and
a cross-model feature fusion module coupled to the lithography simulator and the object detector and configured to generate potential abnormal hotspot data corresponding to the circuit layout data based on the plurality of layout pattern feature matrices and the layout deformation feature matrix;
wherein the circuit layout data comprises at least one circuit layout layer, and the potential abnormal hotspot data comprises a location and a size of at least one potential abnormal hotspot.

2. The system of claim 1, wherein the lithography simulator comprises:
a plurality of feature layers coupled to one another and configured to receive the circuit layout data, wherein a portion of the plurality of feature layers comprises a plurality of skip feature layers;
wherein the plurality of skip feature layers are configured to establish connections between non-adjacent feature layers of the plurality of feature layers so as to increase efficiency of the plurality of feature layers in transmitting a gradient signal.

3. The system of claim 1, wherein the lithography simulator is trained by using the circuit layout training data comprising the at least one circuit layout layer and corresponding binarized electron microscope layout image training data after a lithography or an etching process, so as to minimize a difference between the layout deformation feature matrix and an actual binarized scanning electron microscope (SEM) layout image.

4. The system of claim 1, wherein the object detector comprises:
a plurality of feature channels coupled to one another and configured to receive and transmit the circuit layout data; and
a plurality of feature pyramid network layers coupled to one another and configured to fuse at least two feature channels having different levels to generate the plurality of layout pattern feature matrices.

5. The system of claim 4, wherein the object detector further comprises:
a channel-wise attention module coupled to a deepest feature channel of the plurality of feature channels, and a coarsest feature pyramid network layer of the plurality of feature pyramid network layers, and configured to enhance a shape representation property of a feature tensor transmitted in the object detector.

6. The system of claim 4, wherein the plurality of feature channels of the object detector correspond to layout information having different scales, and a portion of the plurality of feature pyramid network layers are coupled to a portion of the plurality of feature channels and configured to fuse the portion of the plurality of feature channels having different levels.

7. The system of claim 1, wherein the cross-model feature fusion module comprises:
a plurality of cross-model feature fusion units, wherein each cross-model feature fusion unit is coupled to a corresponding pyramid network layer and the lithography simulator, and configured to receive the layout deformation feature matrix and a corresponding layout pattern feature matrix.

8. The system of claim 7, wherein the cross-model feature fusion module further comprises:
a plurality of prediction modules, wherein each prediction module is coupled to a corresponding cross-model feature fusion unit, and the plurality of prediction modules are configured to output the potential abnormal hotspot data.

9. The system of claim 8, wherein each of the prediction modules comprises a classification subnet and a bounding box regression subnet.

10. The system of claim 9, wherein the plurality of prediction modules preset a plurality of anchors previously defined, the classification subnet is configured to predict whether each anchor comprises the at least one potential abnormal hotspot, and configured to predict a category of the least one potential abnormal hotspot, and the bounding box regression subnet is configured to predict the location and the size of the at least one potential abnormal hotspot.

11. The system of claim 7, wherein each of the plurality of cross-model feature fusion units comprises:
a first self-attention module coupled to the lithography simulator and configured to receive the layout deformation feature matrix;
a second self-attention module coupled to the object detector and configured to receive a layout pattern feature matrix; and
a cross-attention module coupled to the first self-attention module and the second self-attention module and configured to generate a fused feature matrix.

12. The system of claim 11, wherein the layout deformation feature matrix is processed by a global average pooling layer to reduce a spatial dimension of the layout deformation feature matrix to be the same dimension as the plurality of layout pattern feature matrices.

13. The system of claim 11, wherein the first self-attention module generates a first key tensor matrix, a first value tensor matrix, and a first query tensor matrix based on the layout deformation feature matrix.

14. The system of claim 13, wherein the first self-attention module comprises a first cache, and the first key tensor matrix, the first value tensor matrix, and the first query tensor matrix are buffered in the first cache and configured to generate an enhanced layout deformation feature matrix.

15. The system of claim 11, wherein the second self-attention module generates a second key tensor matrix, a second value tensor matrix, and a second query tensor matrix based on the layout pattern feature matrix.

16. The system of claim 15, wherein the second self-attention module comprises a second cache, and the second key tensor matrix, the second value tensor matrix, and the second query tensor matrix are buffered in the second cache and configured to generate an enhanced layout pattern feature matrix.

17. The system of claim 11, wherein the cross-attention module generates a third query tensor matrix based on an output of the first self-attention module, and the cross-attention module generates a third key tensor matrix and a third value tensor matrix based on an output of the second self-attention module.

18. The system of claim 17, wherein the cross-attention module comprises a third cache, and the third key tensor matrix, the third value tensor matrix, and the third query tensor matrix are buffered in the third cache and configured to generate the fused feature matrix.

19. The system of claim 1, wherein the circuit layout data comprises an n-th circuit layout layer and preceding (n−1) circuit layout layers, and the potential abnormal hotspot data comprises abnormal hotspot data of the n-th circuit layout layer.

20. The system of claim 1, wherein the layout deformation feature matrix is generated based on a deformation map.
